(19) United States
(12) Patent Application Publication
(10) Pub. No.: US 2005/0040761 A1
(43) Pub. Date: Feb. 24, 2005

(54) Electroluminescent display device

(75) Inventor: Shoichiro Matsumoto, Gifu (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 10/891,455

(22) Filed: Jul. 15, 2004

(30) Foreign Application Priority Data
Jul. 16, 2003 (JP) 2003-275039

(51) Int. Cl. H01J 1/62

(52) U.S. Cl. 313/507; 313/504

(57) ABSTRACT

This invention provides an organic EL display device having a touch panel function and improves accuracy in positional detection on a display portion. First and second light source portions provided along first and second sides of a display portion and first and second light detecting portions provided along sides opposite from the first and second sides are integrally formed on a same glass substrate as a display panel. The display portion is disposed with a plurality of display pixels each having a display organic EL element in a matrix. A plurality of light source organic EL elements is aligned in the first and second light source portions, and a plurality of light sensors is aligned in the first and second light detecting portions.

### CROSS-REFERENCE OF THE INVENTION

This invention is based on Japanese Patent Application No. 2003-275039, the content of which is incorporated by reference in its entirety.

### BACKGROUND OF THE INVENTION

1. Field of the Invention

This invention relates to an electroluminescent display device, particularly to such a device having a touch panel function.

2. Description of the Related Art

In recent years, an organic electroluminescent (hereafter, referred to as EL) display device using EL elements is receiving attention as a display device substituting for a CRT or an LCD. Particularly, an organic EL display device having thin film transistors (hereafter, referred to as TFTs) as switching elements for driving the organic EL elements has been developed.

The LCD has a wide range of applications, for example, from displays for cellular phones and to those for personal digital assistants. Furthermore, a touch panel used with a finger or a pen-type pointing device has been developed.

Such technologies are disclosed in the Japanese Patent Application Publication Nos. 2002-175029 and 2002-214583.

However, the organic EL display device has not been applied to touch panels used with the finger or the pen-type pointing device.

### SUMMARY OF THE INVENTION

This invention provides an organic EL display device having a touch panel function, and is directed to improving accuracy in positional detection on a display portion of such an organic EL display device. An organic EL display device of the invention is formed with a display portion by disposing display pixels each having a display organic EL element in a matrix. A first light source portion having a plurality of light source organic EL elements is provided, being disposed along a first side of the display portion. A first light detecting portion having a plurality of light sensors is provided, being disposed along a side facing to the first side. Similarly, a second light source portion having a plurality of light source organic EL elements is provided, being disposed along a second side of the display portion. A second light detecting portion having a plurality of light sensors is provided, being disposed along a side facing to the second side. The display portion, the first and second light source portions, and the first and second light detecting portions are formed on the same substrate.

In this invention, an organic EL display device having a touch panel function can be realized in one display panel. This reduces the number of components in the display device, and the display device can be miniaturized. Furthermore, a light shielding film provided in a light detecting portion reduces detection errors caused by exterior light and improves accuracy in detection of x and y coordinates on a display portion.

### BRIEF DESCRIPTION OF THE DRAWINGS

FIG. 1A is a plan view of an organic EL display device of an embodiment of the invention, FIG. 1B is a cross-sectional view of FIG. 1A along line A-A, and FIG. 1C is a cross-sectional view of FIG. 1A along line B-B.

FIGS. 2A, 2B and 2C are schematic plan views of a display panel showing an operation of the organic EL display device of the embodiment of the invention.

FIG. 3A is a view showing an upper surface of first and second light detecting portions of FIGS. 1A, 1B and 1C, and FIG. 3B is a cross-sectional view of FIG. 3A along line C-C.

FIG. 4 is a view showing an upper surface of the first and second light detecting portions of FIGS. 1A, 1B and 1C.

### DETAILED DESCRIPTION OF THE INVENTION

A structure of an organic EL display device of one embodiment of the invention will be described with reference to the drawings.

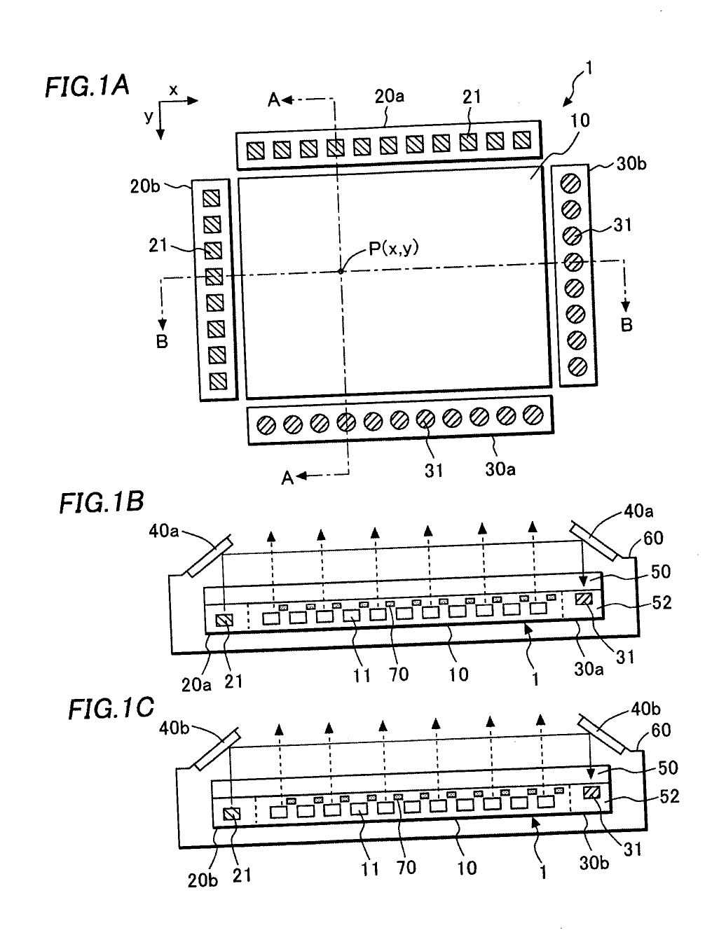

FIG. 1A is a plan view of the organic EL display device of this embodiment. FIG. 1B is a cross-sectional view of FIG. 1A along line A-A. FIG. 1C is a cross-sectional view of FIG. 1A along line B-B.

In this embodiment, in a display portion 10 of a display panel 1, a plurality of display pixels (not shown) is disposed in a matrix. Each of the display pixels includes a display organic EL element 11, a pixel selecting TFT (thin film transistor) 70, a driving TFT (not shown) for driving the display organic EL element 11, and so on.

As shown in FIG. 1A, the display portion 10 is shaped in a rectangle in the plan view, and provided with a first light source portion 20a along a first side of the display portion 10. A plurality of light source organic EL elements 21 is aligned in the first light source portion 20a. Furthermore, a first light detecting portion 30a is provided along a side opposite from the first side of the display portion 10. A plurality of light sensors 31 (e.g. photodiodes) is aligned in the first light detecting portion 30a. The light sensor 31 generates a predetermined current or voltage when receiving light, and the current or the voltage is electrically detected so that the light can be detected.

Similarly, a second light source portion 20b is placed along a second side of the display portion 10. A plurality of light source organic EL elements 21 is aligned in the second light source portion 20b. A second light detecting portion 30b is provided along a side opposite from the second side of the display portion 10. A plurality of light sensors 31 (e.g. photodiodes) is aligned in the second light detecting portion 30b.

A pair of first light reflecting boards 40a is provided above the first light source portion 20a and the first light detecting portion 30a (FIG. 1B). One of these first light reflecting boards 40a reflects light, which is emitted in a vertical direction through a glass substrate 50 from the light source organic EL element 21 of the first light source portion 20a through the glass substrate 50, in a horizontal direction along the glass substrate 50. When this light is not blocked by a pointing object PT (not shown) such as a pen or a finger which touches or is placed close to the display portion 10, another of the first light reflecting boards 40a then reflects the light in a vertical direction through the glass substrate 50, and the reflected light enters the first light detecting portion 30a.

A pair of second light reflecting boards 40b is provided above the second light source portion 20b and the second light detecting portion 30b (FIG. 1C). One of these second light reflecting boards 40b reflects light, which is emitted in a vertical direction through the glass substrate 50 from the light source organic EL element 21 of the second light source portion 20b, in a horizontal direction along the glass substrate 50. When this light is not blocked by the pointing object PT which touches or is placed close to the display portion 10, another of the second light reflecting boards 40b then reflects the light in a vertical direction through the glass substrate 50, and the reflected light enters the second light detecting portion 30b.

Here, the display portion 10 provided with the plurality of the display organic EL elements 11, the first and second light source portions 20a and 20b, and the first and second light detecting portions 30a and 30b are provided in an insulating film 52 on the same glass substrate 50, being integrally formed in a display panel 1. That is, the light source organic EL elements 21 of the first and second light source portions 20a and 20b have the same structure as that of the display organic EL elements 11 of the display portion 10 so that the light source organic EL elements 21 and the display organic EL elements 11 are formed by the same manufacturing steps. Furthermore, the light sensors 31 of the first and second light detecting portions 30a and 30b can be formed of TFTs 70 so that the light sensors 31 can be formed by the same manufacturing steps as the steps for manufacturing the pixel selecting TFTs 70 and the driving TFTs in the display portion 10.

Furthermore, when a drive circuit is provided in the display panel 1 to supply signals to the TFTs 70, the light sensors 31 are also formed through the same manufacturing steps as the steps for manufacturing the TFTs 70 in the drive circuit.

This display panel 1 is stored in a storage container 60, and the display portion 10 is exposed through a window of the storage container 60. This display panel 1 is thus configured to emit display light of the display portion 10 outside.

Next, a detection process of a point P corresponding to a position where the pointing object PT touches or is placed close to the display portion 10 will be described with reference to FIGS. 1A, 1B, and 1C.

The coordinates (x, y) of this point P are determined as follows. Assume that the x coordinate corresponds to the first side of the display portion 10, and the y coordinate corresponds to the second side of the display portion 10. Furthermore, light emitted from each of the light source organic EL elements 21 of the first and second light source portions 20a and 20b has directivity similar to those of laser beams.

First, the x coordinate of the point P is determined as described below. Light emitted in a vertical direction through the glass substrate 50 from each of the light source organic EL elements 21 of the first light source portion 20a is reflected in a horizontal direction along the glass substrate 50 by one of the first light reflecting boards 40a. When the light is not blocked by the pointing object PT, the light is then reflected in a vertical direction through the glass substrate 50 by another of the first light reflecting boards 40a to enter the first light detecting portion 30a. The light entering the first light detecting portion 30a is detected by the light sensors 31 corresponding to the positions where the light enters. On the other hand, when the light is blocked by the pointing object PT, light emitted from the light source organic EL element 21 of the first light source portion 20a is blocked by the pointing object PT so that the light is not detected by the light sensor 31 corresponding to the position where the light does not enter. Therefore, the position of this light sensor 31 which does not detect the light corresponds to the x coordinate of the point P on the display portion 10.

Next, the y coordinate of the point P is determined as described below. Light emitted in a vertical direction through the glass substrate 50 from each of the light source organic EL elements 21 of the second light source portion 20b is reflected in a horizontal direction along the glass substrate 50 by one of the second light reflecting boards 40b. When the light is not blocked by the pointing object PT, the light is then reflected in a vertical direction through the glass substrate 50 by another of the second light reflecting boards 40b to enter the second light detecting portion 30b. The light entering the second light detecting portion 30b is detected by the light sensors 31 corresponding to the positions where the light enters. On the other hand, when the light is blocked by the pointing object PT, light emitted from the light source organic EL element 21 of the second light source portion 20b is blocked by the pointing object PT so that the light is not detected by the light sensor 31 corresponding to the position where the light does not enter. Therefore, the position of this light sensor 31 which does not detect the light corresponds to the y coordinate of the point P on the display portion 10.

When light emitted from each of the light source organic EL elements 21 of the first and second light source portions 20a and 20b does not have directivity similar to those of laser beams, the x and y coordinates of the point P (x, y) can be determined as described below.

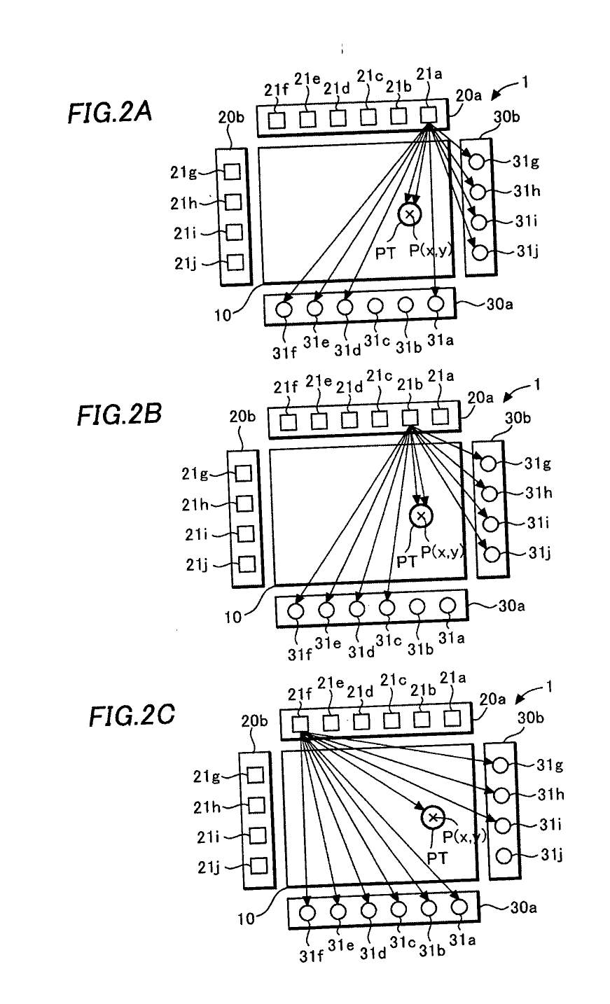

That is, the x and y coordinates of the point P (x, y) are determined by sequentially switching the light source organic EL elements for emitting light, and by monitoring the positions of the light sensors which do not detect the light each time. A process of determining the x and y coordinates of the point P (x, y) in this case will be described with reference to FIGS. 2A, 2B, and 2C.

FIGS. 2A, 2B and 2C are schematic plan views of the display panel 1 explaining an example of a process of determining the x and y coordinates of the point P (x, y) under the divergent light source. In FIGS. 2A, 2B and 2C, the number of the light source organic EL elements and the light sensors is reduced from the number shown in FIG. 1A for simplifying description.

As shown in FIG. 2A, light is emitted in a vertical direction through the glass substrate 50 (not shown) from a light source organic EL element 21a provided in one end of the first light source portion 20a. This light is reflected in a horizontal direction along the glass substrate 50 by the first light reflecting board 40a (not shown) provided above the first light source portion 20a.

When the light reflected in a horizontal direction is not blocked by the pointing object PT, the light is then reflected in a vertical direction of the display panel 1 by the first light reflecting board 40a (not shown) provided above the first light detecting portion 30a to enter the first light detecting portion 30a. Furthermore, the light is reflected in a vertical direction of the display panel 1 by the second light reflecting board 40b (not shown) provided above the second light detecting portion 30b to enter the second light detecting portion 30b. The light entering the first and second light detecting portions 30a and 30b is detected by the light sensors corresponding to positions where the light enters (light sensors 31a, 31d, 31e, 31f, 31g, 31h, 31i, and 31j in an example of FIG. 2A).

On the other hand, when the light reflected in a horizontal direction is blocked by the pointing object PT, the light is blocked by the pointing object PT so that the light does not enter the first and second light detecting portions 30a and 30b. That is, the light sensors (light sensors 31b and 31c in an example of FIG. 2A) corresponding to positions where the light does not enter do not detect the light.

Accordingly, the light sensors which do not detect the light are searched among the light sensors of the first and second light detecting portions 30a and 30b, and x coordinates or y coordinates of those light sensors are stored in a storage medium (not shown) such as a memory. When this operation is completed, the light source organic EL element 21a is turned off the light.

Next, as shown in FIG. 2B, light is emitted from a light source organic EL element 21b adjacent the light source organic EL elements 21a. Then, x coordinates or y coordinates of the light sensors (light sensors 31a and 31b in an example of FIG. 2B) which do not detect the light among the light sensors of the first and second light detecting portions 30a and 30b are stored in the memory (not shown) and so on. When this operation is completed, the light source organic EL element 21b is turned off the light.

Similarly, light source organic EL elements 21c, 21d, 21e and 21f placed adjacent each other in the first light source portion 20a are sequentially switched to emit light and turn off the light. The light sensors which do not detect the light are searched each time, and x coordinates or y coordinates of the light sensors are stored in the memory (not shown) and so on. As shown in FIG. 2C, when light is emitted from the light source organic EL element 21f, an x coordinate or a y coordinate of the light sensor (light sensor 31j in an example of FIG. 2C) which does not detect the light is stored in the memory (not shown) and so on.

After a sequence of light emission and turn-off is completed from the light source organic EL element 21a provided on one end of the first light source portion 20a to the light source organic EL element 21f provided on another end thereof, the light emission and turn-off in the second light source portion 20b are sequentially performed from the light source organic EL element 21g provided on one end thereof to the light source organic EL element 21j provided on another end thereof. At each time of this operation, the light sensors which do not detect the light are searched in the first and second light detecting portions 30a and 30b, and x or y coordinates corresponding to the light sensors are monitored and stored in the memory and so on (not shown).

As described above, the light sensors of the first and second light detecting portions 30a and 30b, which do not detect the light emitted from the first and second light source portions 20a and 20b, are searched. The x coordinate or the y coordinate corresponding to each of the detected light sensors is monitored each time, and stored in the memory (not shown) and so on.

Then, the x or y coordinates of the light sensors which do not detect the light, which are monitored and stored each time, are used to determine the x and y coordinates of the point P (x, y) representing the location of the pointing object PT that touches or is placed close to the display portion 10. Then, the data stored in the memory and so on are initialized for next detection of the point P (x, y).

Next, description will be made on a structure (not shown) of the display organic EL element 11 of the display portion 10 and the light source organic EL element 21 of the first and second light source portions 20a and 20b.

When having a so-called bottom emission type, in which an EL element emits light through the substrate formed with an EL element, the display organic EL element 11 and the light source organic EL element 21 include a first electrode, a hole transport layer, an emissive layer, an electron transport layer and a second electrode in this order. The first electrode is a transparent electrode made of ITO (indium tin oxide) and so on. The hole transport layer is formed of a first hole transport layer made of MTDATA (4,4-bis(3-methylphenylphenylamino) biphenyl) and a second hole transport layer made of TPD (4,4,4-tris (3-methylphenylphenylamino)triphenylamine). The emissive layer is made of Bebq2 (bis(10-hydroxybenzo[h]quinolinato)beryllium) containing quinacridone, and the electron transport layer is made of Bebq2. The second electrode is made of magnesium indium alloy, aluminum or aluminum alloy.

In these display organic EL element 11 and the light source organic EL element 21, holes injected from the first electrode and electrons injected from the second electrode are recombined inside the emissive layer. These recombined holes and electrons activate organic molecules forming the emissive layer to generate excitons. Light is emitted from the emissive layer in a process of radiation of the excitons, and then released outside after going through the transparent first electrode to the glass substrate 50, thereby completing light-emission.

Next, a structure of the first and second light detecting portions 30a and 30b is described with reference to the drawings.

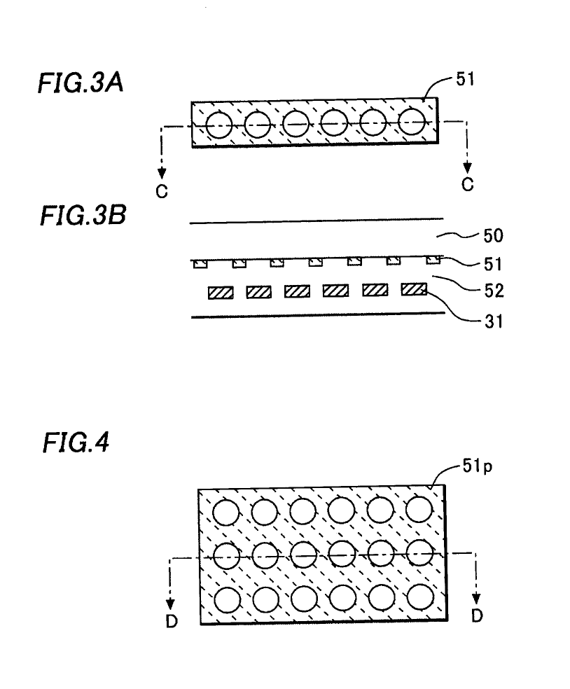

FIG. 3A shows an upper surface of each of the first and second light detecting portions 30a and 30b. FIG. 3B is a cross-sectional view of FIG. 3A along line C-C.

As shown in FIG. 3A, the first and second light detecting portions 30a and 30b are formed with a light shielding film 51 having openings in positions corresponding to the light sensors 31. That is, as shown in FIG. 3B, an insulating film 52 is formed on the glass substrate 10, and the plurality of the light sensors 31 are formed in this insulating film 52. A plurality of the light shielding film 51 is formed only between the adjacent light sensors 31. These light shielding films 51 are formed on the glass substrate 50. Although exterior light enters the first and second light detecting portions 30a and 30b from an outside of the display panel 1, these light shielding films 51 can block (or reduce) the exterior light from reaching the light sensors 31.

Therefore, when the position of the point P is detected as described above, the light shielding films 51 provided between the plurality of the adjacent light detecting sensors 31 enable detection of only light having an incident angle approximately normal to the light sensors 31. This reduces detection errors caused by exterior light entering the first and second light detecting portions 30a and 30b, thereby improving accuracy in detection of the x and y coordinates of the point P.

Although the light sensor 31 is formed of, for example, a photodiode in the above embodiment, the light sensor 31 can be formed of a plurality of the photodiodes connected in parallel. The parallel connection of the photodiodes improves accuracy in light detection of the light sensor 31. The photodiode can be formed by connection (diode connection) between gates and sources of TFTs 70. A view of an upper surface of the first and second light detecting portions 30c and 30d in this case is shown in FIG. 4. A cross-sectional view of FIG. 4 along a line D-D is the same as FIG. 3B.

Although the light sensor 31 is formed of, for example, a photodiode in the above embodiment, the light sensor 31 can be formed of a photoelectron device other than the photodiode.

Although the display device of the above embodiment is an active matrix display device in which TFTs are formed in each of pixels, the invention is not limited to this but the display device can be a passive matrix display device in which TFTs are not formed in each of pixels.

The above embodiment can be applied to an EL display device of bottom emission type in which light emitted from an EL element is released outside through the glass substrate 50 formed with an EL element. Furthermore, the embodiment can be applied to an EL display device of top emission type, in which light emitted from an EL element is released through the glass substrate opposite from the glass substrate having TFTs thereon.

Although the openings formed in the light shielding films 51 and 51P are shaped in a circle, the invention is not limited to this but the openings can have other shapes as long as the openings can transmit light from the light source organic EL element 21 and block exterior light.

As described above, the light source for detecting the pointing object is formed of the same organic EL element as that used for the display organic EL element 11. Therefore, it is unnecessary to form the light source for detecting the pointing objects from other element. Accordingly, both the display and light source organic EL elements can be formed simultaneously. It is noted that the light source organic EL elements may be formed separately from the display organic EL elements, for example, when different light intensities are required for the two different types of organic EL elements.

Since the light sensor 31 is formed of TFTs, the light sensor and the pixel can be formed simultaneously in the active matrix EL display device having TFTs in each of pixels. Furthermore, the above embodiment can be applied to a non-organic EL element having an emissive layer made of non-organic materials.

Accordingly, an EL display device having a described touch panel function can be realized without increasing the number of steps.

1. An electroluminescent display device comprising:
a display portion comprising a plurality of display electroluminescent elements arranged in a matrix;
a first light source portion having a plurality of light source electroluminescent elements and disposed along a first side of the display portion;
a first light detecting portion having a plurality of light sensors and disposed along a side of the display portion opposite from the first side;
a second light source portion having a plurality of light source electroluminescent elements and disposed along a second side of the display portion;
a second light detecting portion having a plurality of light sensors and disposed along a side of the display portion opposite from the second side; and
a substrate,
wherein the display portion, the first and second light source portions, and the first and second light detecting portions are formed on the substrate.

2. The electroluminescent display device of claim 1, further comprising a light shielding film provided on a top surface of each of the first and second light detecting portions such that the top surface is covered by the shielding film between the light sensors.

3. The electroluminescent display device of claim 1, wherein each of the light sensors of the first and second light detecting portions comprises a photodiode.

4. The electroluminescent display device of claim 1, wherein each of the light sensors of the first and second light detecting portions comprises a plurality of photodiodes connected in parallel.

5. The electroluminescent display device of claim 1, wherein the electroluminescent display device is an electroluminescent display device of active type having a switching element for each of the display electroluminescent elements.

6. The electroluminescent display device of claim 1, wherein the display electroluminescent elements and the light source electroluminescent elements include a same structure.

7. The electroluminescent display device of claim 5, wherein the switching elements and the light sensors include a same structure.

8. An electroluminescent display device comprising:
a display portion comprising a plurality of display electroluminescent elements arranged in a matrix;
a first light source portion having a plurality of light source electroluminescent elements and disposed along a first side of the display portion;
a first light detecting portion having a plurality of light sensors and disposed along a side of the display portion opposite from the first side;
a second light source portion having a plurality of light source electroluminescent elements and disposed along a second side of the display portion;
a second light detecting portion having a plurality of light sensors and disposed along a side of the display portion opposite from the second side;
a substrate;
a first light reflecting portion reflecting light from the first light source portion in a direction parallel to the substrate;
a second light reflecting portion reflecting the light reflected by the first light reflecting portion in a direction normal to the substrate so as to lead the light to the first light detecting portion;
a third light reflecting portion reflecting light from the second light source portion in a direction parallel to the substrate;
a fourth light reflecting portion reflecting the light reflected by the third light reflecting portion in a direction normal to the substrate so as to lead the light to the second light detecting portion;
wherein the display portion, the first and second light source portions, and the first and second light detecting portions are formed on the substrate.

9. The electroluminescent display device of claim 8, further comprising a light shielding film provided on a top surface of each of the first and second light detecting portions such that the top surface is covered by the shielding film between the light sensors.

10. The electroluminescent display device of claim 8, wherein each of the light sensors of the first and second light detecting portions comprises a photodiode.

11. The electroluminescent display device of claim 8, wherein each of the light sensors of the first and second light detecting portions comprises a plurality of photodiodes connected in parallel.

12. The electroluminescent display device of claim 8, wherein the electroluminescent display device is an electroluminescent display device of active type having a switching element for each of the display electroluminescent elements.

13. The electroluminescent display device of claim 8, wherein the display electroluminescent elements and the light source electroluminescent elements include a same structure.

14. The electroluminescent display device of claim 12, wherein the switching elements and the light sensors include a same structure.
